(19) United States
(12) Patent Application Publication
(10) Pub. No.: US 2012/0033479 A1
(43) Pub. Date: Feb. 9, 2012

(54) MODIFICATION OF LOGIC BY MORPHOLOGICAL MANIPULATION OF A SEMICONDUCTOR RESISTIVE ELEMENT

(75) Inventors: John M. DeLucca, Wayne, PA (US); James Cargo, Bethlehem, PA (US); Frank A. Baiocchi, Allentown, PA (US)

(73) Assignee: LSI Corporation, Milpitas, CA (US)

(21) Appl. No.: 12/852,378

(22) Filed: Aug. 6, 2010

(51) Int. Cl. G11C 11/00; H05K 3/36

(52) U.S. Cl. 365/148; 29/830

(57) ABSTRACT

An electronic device includes a substrate with a resistive element located thereover. The resistive element includes a semiconductor region. A read module is configured to determine a resistance of the resistive element. A programming module is configured to cause a current to flow through the semiconductor region. The current is sufficient to induce a change of morphology of at least a portion of the semiconductor region.

This application is related to PCT Application No. PCT/US08/76976 filed by Frank A. Baiocchi, et al. on Sep. 19, 2008, entitled “Allotropic Change in Silicon Induced by Electromagnetic Radiation for Resistance Tuning of Integrated Circuits”, commonly assigned with this application and incorporated herein by reference; and co-pending U.S. patent application Ser. No. ______ (attorney docket number L09-0628US1) filed by John DeLucca, et al., entitled “Modification of Semiconductor Optical Paths by Morphological Manipulation”, commonly assigned with this application and incorporated herein by reference.

### TECHNICAL FIELD

This application is directed, in general, to an electronic device and, more specifically, to reconfiguring an operation thereof.

### BACKGROUND

In some circumstances it is desirable to reconfigure an operational aspect of an electronic device. Such reconfiguration may be for the purpose, e.g., of storing information, or changing a function provided by the device. Various existing methods suffer from one or more deficiencies, such as damage to the electronic device (e.g. radiation-induced soft errors), a limited number of reconfiguration cycles that may be performed on the device, complex processing steps or exotic materials.

### SUMMARY

One embodiment provides an electronic device having a substrate. The electronic device includes a resistive element located thereover that includes a semiconductor region. A read module is configured to determine a resistance of the resistive element. A programming module is configured to cause a current to flow through the semiconductor region. The current is sufficient to induce a change of morphology of at least a portion of the semiconductor region.

Another embodiment provides an electronic device. The electronic device includes a substrate and a resistive element located thereover. The resistive element is configured to receive a read current. The resistive element includes an amorphous region and a crystalline region of a semiconductor material. The amorphous and crystalline regions form an intimate interface therebetween.

Another embodiment provides a method of forming an electronic device. A substrate is provided that has a semiconductor region located thereover configured to receive a current. The semiconductor region has a morphology of a first type. At least a portion of the semiconductor region is converted to a morphology of a different second type. The semiconductor region is resistively coupled to a read module. The read module is configured to convert a resistance of the semiconductor region to a logic level.

### BRIEF DESCRIPTION

Reference is now made to the following descriptions taken in conjunction with the accompanying drawings, in which:

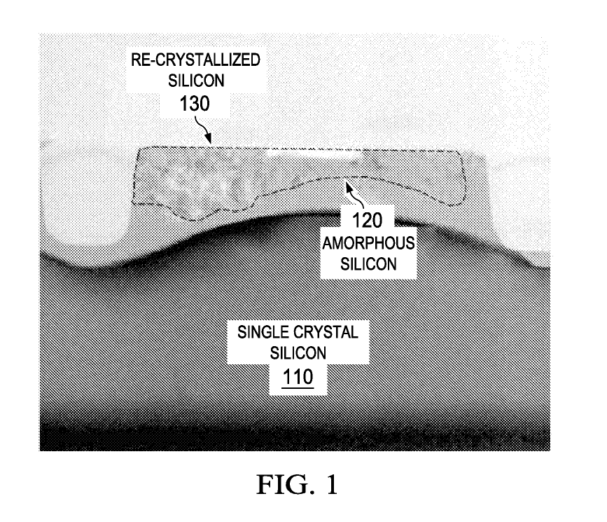

FIG. 1 is a micrograph of a semiconductor layer after optical illumination;

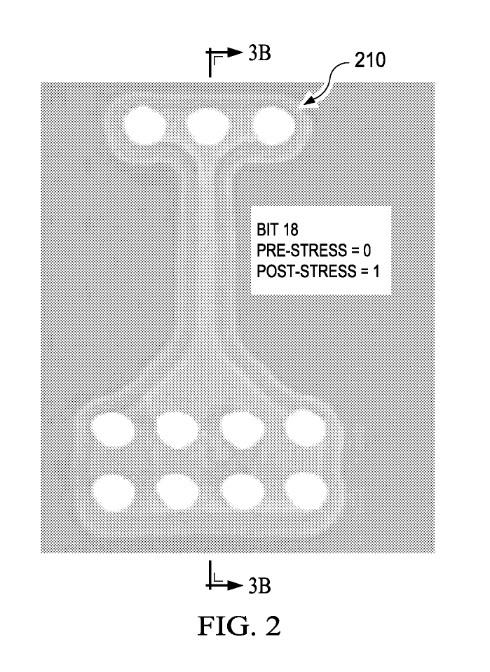

FIG. 2 is a micrograph of a semiconductor resistor after being subjected to an electrical stress;

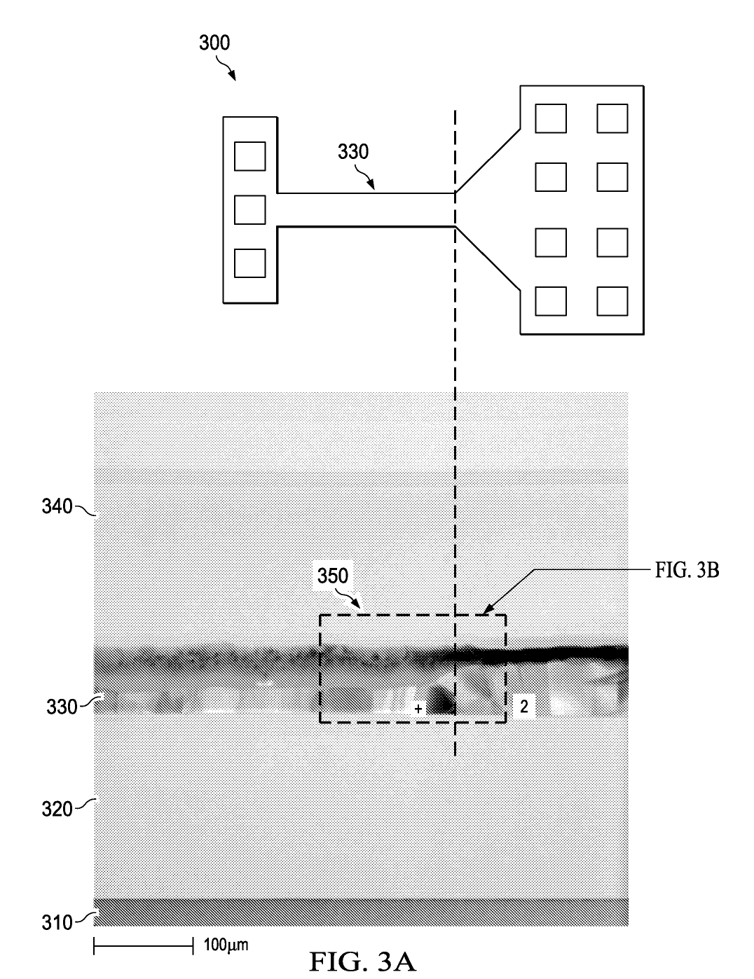

FIGS. 3A and 3B are micrographs of a sectioned resistor after exposure to electrical stimulus;

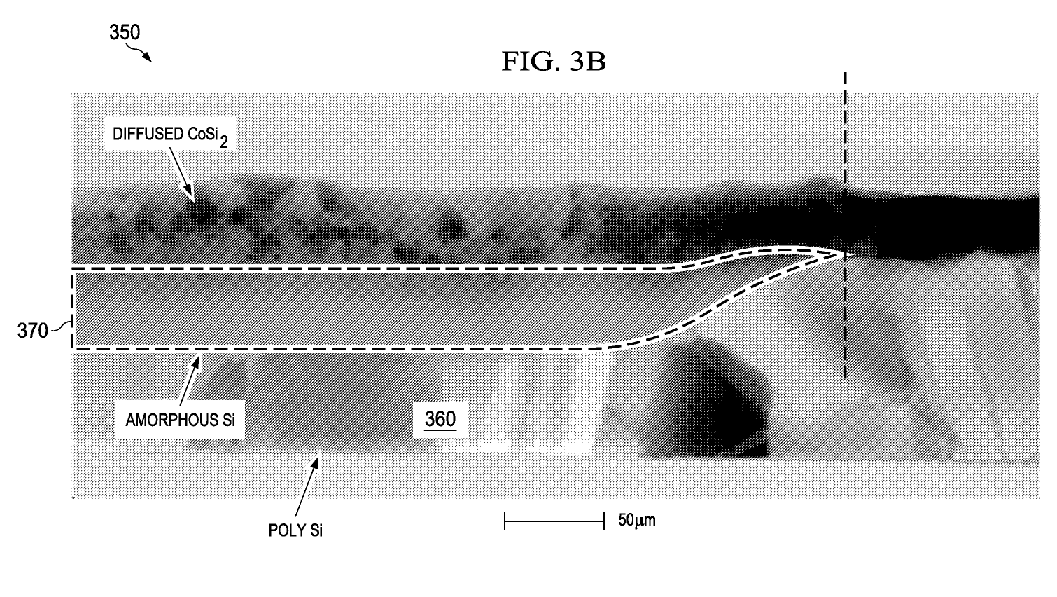

FIG. 4 illustrates an electronic device including a resistive element configured to be programmed by a first current and read by a second current;

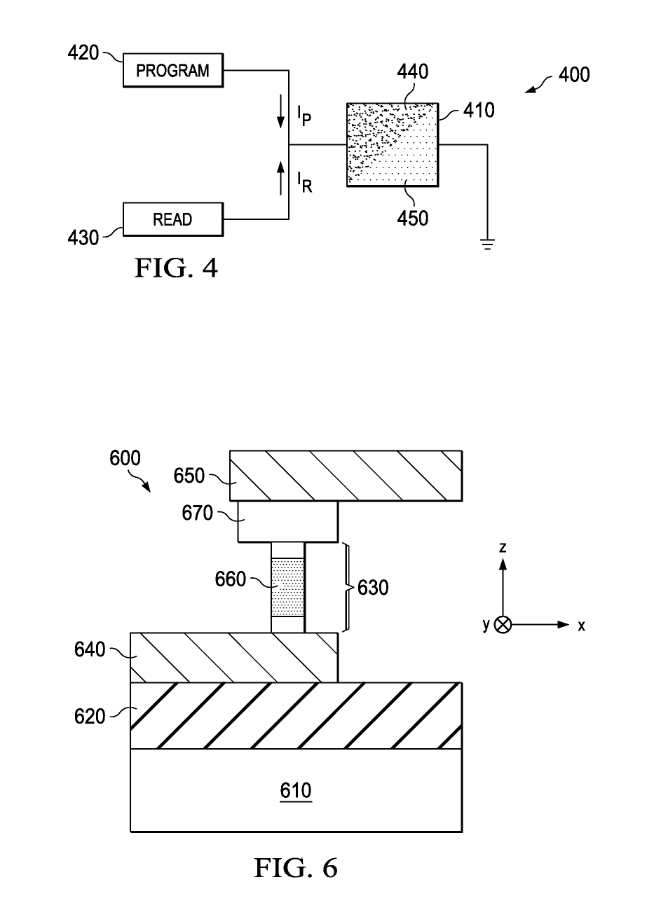

FIG. 5 presents a top and a sectional view of an embodiment of a lateral resistive storage cell;

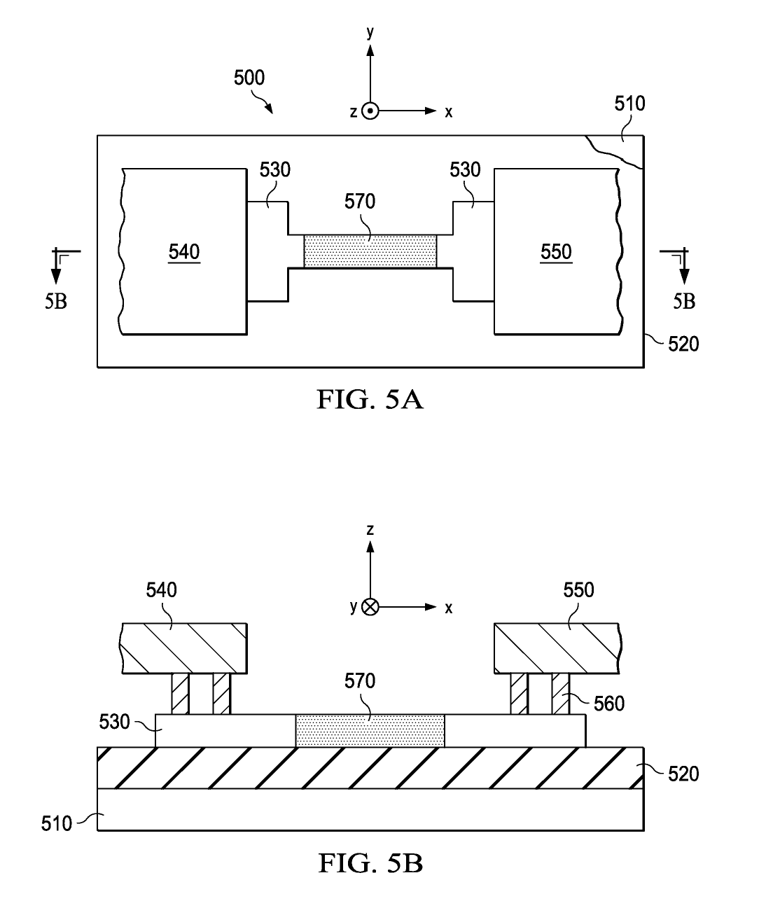

FIG. 6 illustrates an embodiment of a vertical resistive storage cell;

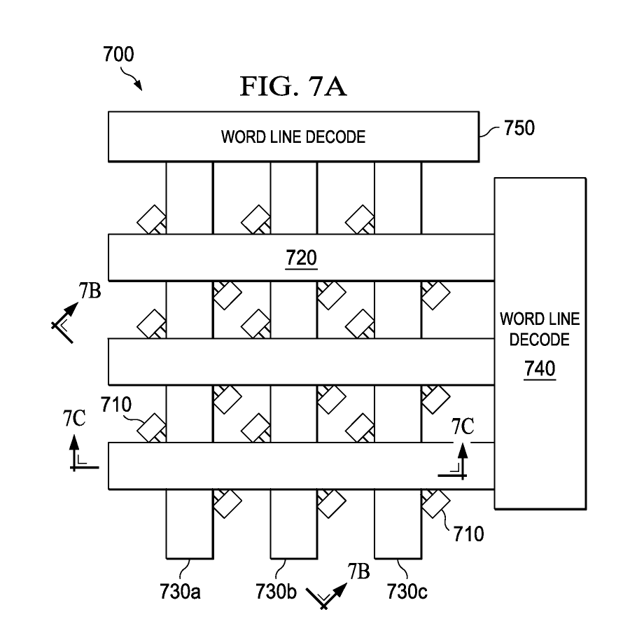

FIG. 7A illustrates a top view of resistive elements located at intersections of word lines and bit lines of a resistive memory array;

FIG. 7B illustrates a sectional view through one of the resistive elements of FIG. 7A through the long axis of the resistive element;

FIG. 7C illustrates a sectional view of resistive elements of FIG. 7A, each element configured to represent one of three logic levels;

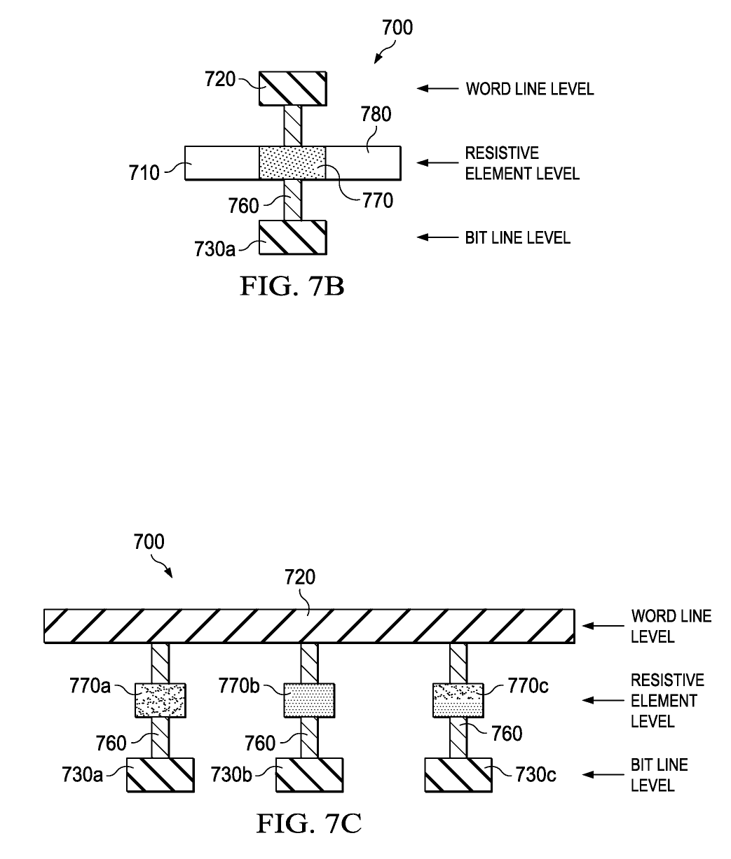

FIGS. 8A and 8B illustrate a method of forming an electronic device, e.g. the electronic device of FIG. 4;

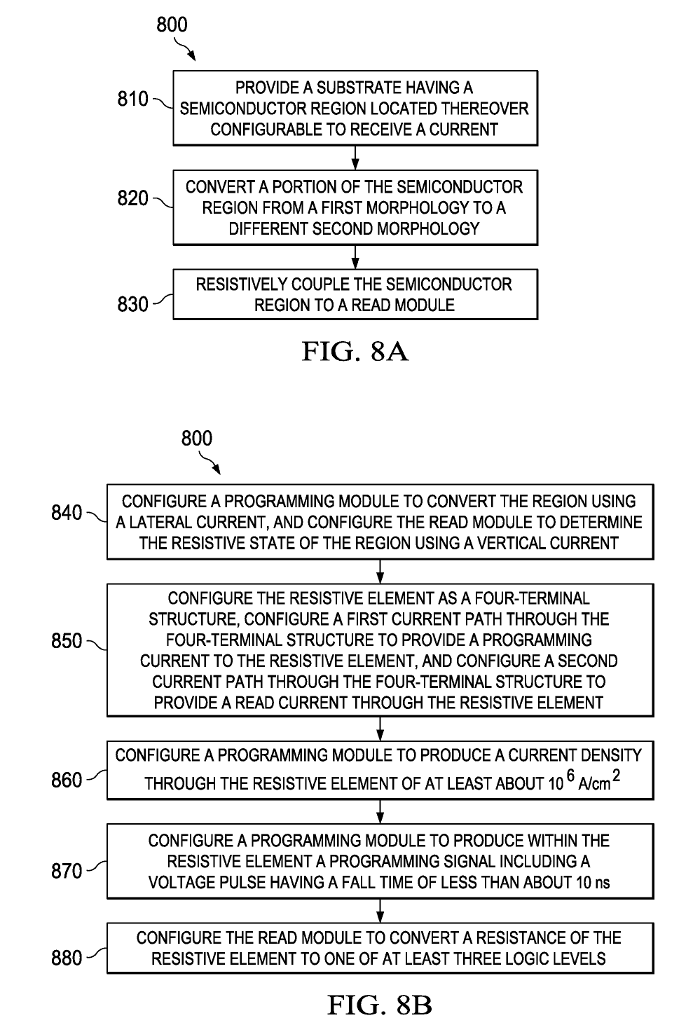

FIGS. 9A and 9B illustrate example programming profiles that may be used to program the resistive element of FIG. 4; and

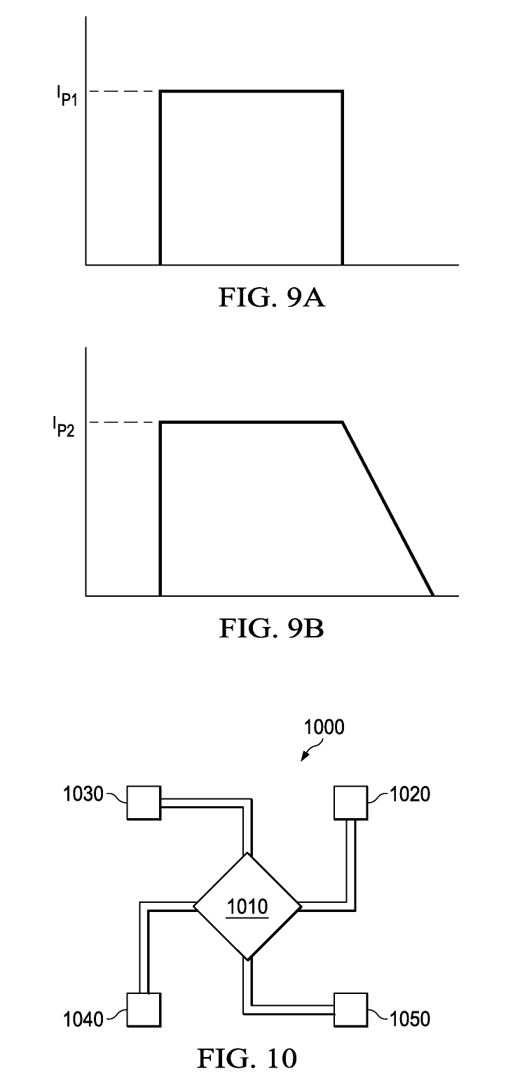

FIG. 10 illustrates a four-terminal structure that may be used in some embodiments to program and read the resistance of a resistive element.

### DETAILED DESCRIPTION

This disclosure benefits from the recognition that resistive properties of a semiconductor region in an electronic device may be beneficially modified to alter the operation of the electronic device. Such modification may include heating the semiconductor region to induce a change of morphology of the region. Unlike various conventional approaches, embodiments herein present methods that do not significantly damage the electronic device. Moreover, the properties of the semiconductor region may be reversibly changed. Thus, one or more operational characteristics of the electronic device may be changed from initial characteristics, and later restored to the initial characteristics or to yet another set of characteristics.

This disclosure provides in various embodiments an adjustable resistive element that may be switched between two or more distinct resistance values. As used herein, a resistive element has a continuous conductive path, e.g. the element is not blown to create an electrical “open” at the location of the resistive element. In various embodiments the element is suitable for use in an integrated circuit (IC) design. The resistive element may be used in lieu of, or in combination with, other adjustable circuit elements such as adjustable transistors or capacitors.

In addition, the disclosure includes various embodiments of an array of resistive data storage elements. The storage elements may be used in various embodiments such as, e.g. a part of a memory or a programmable logic array. Such an array may provide higher performance, higher density, and/or higher reliability than various conventional data storage arrays. For example, some memory based on CMOS logic may be degraded by background particle radiation from package materials or ambient electromagnetic radiation. In contrast, the resistive data storage elements described herein are expected to remain substantially unaffected by such radiation, since neither type would provide enough energy to alter the given allotropic phase of the material. In addition, the resistive data storage elements are expected to operate over a wider temperature range than conventional memory storage elements.

The disclosure may refer to various morphologies and allotropes of a semiconductor region. Morphologies include bulk or single-crystalline semiconductor, e.g. an epitaxial layer; amorphous semiconductor, e.g., having periodicity less than a few semiconductor bond lengths; and polycrystalline semiconductor, e.g., having multiple crystalline domains that span more than a few tens (e.g. about 50) of semiconductor bond lengths with arbitrary orientation with respect to each other. A polycrystalline semiconductor may be large-grained or fine-grained. Large-grained means having a mean grain diameter of at least 1 μm. Fine-grained means having a mean grain size less than 1 μm, typically 100 nm or smaller. An allotrope refers to a form of a semiconductor material characterized by general bonding characteristics. Thus, the bulk crystalline and polycrystalline morphologies are both a same allotrope, because the semiconductor atoms are bonded in a crystalline arrangement. The amorphous morphology is a different allotrope, because the semiconductor bonds are in general not well-ordered as they are in a crystal.

Embodiments may be practiced with each of the morphology types with any elemental or compound semiconductor, including without limitation the semiconductor materials Si, Ge, GaAs, InP, SiC, InGaP, InGaAs, and InAlGaP. The semiconductor may be doped or intrinsic. Various embodiments are described using Si as an example semiconductor material. Such use of Si as an example material does not limit the described embodiments to Si. Various embodiments may refer to amorphous Si as a-Si, crystalline Si as c-Si, and polycrystalline Si as p-Si. Those skilled in the pertinent art will appreciate that the principles illustrated by reference to these forms of Si may be extended to other semiconductors within the scope of the disclosure.

Turning now to FIG. 1, illustrated is a single-crystalline silicon substrate 110, a portion of which has been converted to an amorphous region 120 by illuminating the substrate 110 with laser light. PCT Application No. PCT/US08/76976 to Baiocchi, et al. (hereinafter referred to as “the '976 application”), previously incorporated by reference, discloses methods of changing the allotropic and/or morphological type of a semiconductor layer using coherent (laser) energy. In various embodiments described therein, laser energy may be focused on a portion of a semiconductor layer, causing partial melting of the illuminated portion. For example, the energy dose and duration, focus, and time period over which multiple exposures are performed may determine a time-temperature profile that results in the formation of an amorphous or polycrystalline allotrope of the illuminated semiconductor.

In FIG. 1, the amorphous region 120 has been converted from single-crystalline silicon to amorphous silicon using a first optical pulse pattern and/or illumination condition. A portion of the amorphous region 120 has in turn been converted to a polycrystalline region 130 by illuminating the amorphous region 120 with laser light using a second pulse pattern and/or illumination condition. The polycrystalline region 130 may include fine-grained semiconductor material, such as when the recrystallization time is too short to allow large grains to form. In general, the unaltered substrate 110, the amorphous region 120 and the polycrystalline region 130 each have different resistive properties, e.g. resistivity expressed in Ω-cm.

Thus, as described in the '976 application, a bulk crystalline or polycrystalline portion of a semiconductor, e.g., silicon, may be controllably transformed to an amorphous allotrope, and then controllably changed to a polycrystalline allotrope. The conversion may be done without damage to surrounding dielectric layers or an underlying substrate.

The crystalline form of the semiconductor typically has a different resistivity than the amorphous form of the semiconductor. Silicon, as one nonlimiting example, is known to take both crystalline and amorphous allotropes. The intrinsic resistivity of crystalline silicon is about 0.23 MΩ-cm while that of amorphous silicon (a-Si) is on the order of 100 MΩ-cm, a difference of over 400 times.

The change of morphology exemplified in FIG. 1 may also be produced by an electrical stimulus, e.g. resistive heating. The stimulus may be, e.g. a current with a temporal profile configured to deposit a quantity of energy over a short time period into a target region in which the conversion is desired.

FIG. 2 illustrates a resistor 210 implemented in a semiconductor device. The resistor 210 was exposed to an electrical pulse typical of a Charged Device Model (CDM) Electrostatic Discharge (ESD) event. For example, such an event may be characterized by a voltage of 500 V and a current density through the resistive path on the order of 10⁶ A/cm² applied over a time period of about 1 ns. The resistor 210 does not display visible evidence of programming, but the electrical properties are consistent with programming, e.g., an increase of resistance. The physical condition of the resistor 210 indicates that a similar structure may be physically and electrically modified without visible damage thereto or to surrounding structure.

FIG. 3A presents a resistor 300 structure similar to that of the resistor 210 after electrical stressing as described above. Referring to FIG. 3A, the resistor 300 is located over a substrate 310, e.g. a silicon wafer. An oxide layer 320 lies between the substrate 310 and a semiconductor layer 330. An oxide layer 340 overlies the semiconductor layer 330. The semiconductor layer 330 includes a region 350, which originally included only one semiconductor morphology, e.g., p-Si.

FIG. 3B illustrates the region 350 at higher magnification. The region 350 after electrical stressing includes a p-Si portion 360 and an a-Si portion 370. Little or no dimensional change to the resistor 300 is apparent in spite of the energy deposited into the region 330 to effect the change of morphology. Notably, there is no evidence of damage to the oxide layers 320, 340.

The p-Si portion 360 and the a-Si portion 370 form an intimate interface therebetween. Herein and in the claims, an intimate interface is an interface in which semiconductor atoms are shared between the portions 360, 370 and/or the distance between semiconductor atoms on one side of the interface and semiconductor atoms on the other side of the interface is on the order of the atomic lattice spacing of the semiconductor material.

In various embodiments, the electrically-induced change of morphology evidenced in FIGS. 3A and 3B may be exploited in an electronic device. A read module may be conductively coupled to the semiconductor layer 330 such that the resistance thereof may be determined. The resistance may be mapped to one of two or more logic levels, thus providing a means to store information by virtue of the morphological state of the semiconductor layer 330.

FIG. 4 illustrates an electronic device 400 including a resistive element 410. A programming module 420 is configured to program the resistive element 410 with a program current I_{P}. A read module 430 is configured to determine the resistive state of the resistive element 410 with a read current I_{R}. The program module 420 and the read module 430 may optionally be formed on the same substrate as the resistive element 410. The resistive element 410 includes a first region 440 having a first resistivity ρₚ, and a second region 450 having a different second resistivity ρₐ.

The programming module 420 in various embodiments is configured to provide an electrical stimulus similar to the moderate CDM ESD pulse previously described. In some embodiments the programming module 420 is formed over the substrate that supports the resistive element 410. In other words, the resistive element 410 and the programming module 420 may be part of a same integrated circuit. In other embodiments, the programming module 420 is separate from the resistive element 410. In this case, the programming module 420 may be a stand-alone device configured to produce a time and temperature profile that heats the resistive element 410 in a manner that produces a change of morphology as described herein.

Upon application of a suitably configured electrical stimulus, the resistive element 410 may be converted to a more fully amorphous state and the maximum resistance value may be realized. However, after an initial amorphising electrical stimulus, if a further electrical stimulus is applied in order to provide energy to promote atomic mobility and Si recrystallization, an intermediate resistance value may be obtained.

In the following discussion, the first region 440 is illustratively treated as a poly-crystalline semiconductor having resistivity ρ_{c} and the second region 450 is illustratively treated as an amorphous semiconductor having resistivity ρₐ. The total resistance of the resistive element will be closely related to a volume fraction f_{c} of the first region 440 and a volume fraction fₐ=1−f_{c} of the second region 450. The read current I_{R} follows a path having a path length l through the resistive element 410. The path has an associated cross-sectional area A. Thus, the resistance of the resistive element 410 may be expressed as

$$R ≅ \frac{( {f}_{a} {ρ}_{a} + {f}_{c} {ρ}_{c} ) l}{A}$$

The volume fraction fₐ may be changed from the amorphous morphology to the crystalline morphology by heating the resistive element 410 as described previously. The observed alteration of properties, e.g. a change of morphology with little or no observable damage to the resistor 300 or surrounding material layers, may in various embodiments be obtained from a wide range of programming pulse characteristics. For example the pulse voltage may have a value that falls within a range between tens of volts and thousands of volts. Likewise, the pulse may have a duration ranging from less than one nanosecond to a few microseconds. An effective combination of voltage and pulse duration is expected to depend on the specific layout of the structure to which the pulse is applied. Such voltage and duration conditions are determinable by one skilled in the pertinent art. It is expected that the final properties of the programmed resistor will correlate with total energy deposited into the resistor. Thus it is expected that generally as the voltage of the programming pulse increases, the duration of the pulse will decrease, and vice-versa.

FIG. 9A presents an illustrative programming current I_{P1} as a function of time. The current I_{P1} has a profile that increases rapidly, e.g. with a rise time less than about 10 ns, to a maximum value, and decreases rapidly, e.g. with a fall time less than about 10 ns, to a minimum value. Such a programming current is expected to favor the production of amorphous material in the resistive element 410 due to rapid quenching of melted semiconductor material. FIG. 9B illustrates a programming current I_{P2}. The current I_{P2} increases rapidly to its maximum value, but decreases at a slower rate than the current I_{P1}, e.g. greater than about 100 ns. The slower decrease of I_{P2} is expected to favor the production of polycrystalline semiconductor material by providing atomic mobility over a longer period as the material cools. In some cases the polycrystalline semiconductor material is fine-grained, such as when the recrystallization time is short. The relative amounts of amorphous and crystalline material, e.g. fₐ and f_{c} may be controlled by factors such as, e.g. the total energy deposited into the resistive element 410, and the fall time of the programming current.

In a first nonlimiting example, the resistive element 410 may be set to a relatively higher resistance by a 400V programming pulse configured similarly to the CDM ESD event previously described. The programming pulse may be applied by, e.g. an external source. The programming pulse may have a total duration of about 0.5 ns and a rise and fall time ≲0.1 ns. At least a portion of the resistive element 410 is expected to be amorphous after the application of such a pulse. If the portion is amorphous prior to the application of the programming pulse, the resistance of the resistive element 410 may be substantially unchanged, e.g. is interpreted as a high state before and after the programming pulse, e.g. fₐ>0. If the portion is polycrystalline prior to the application of the programming pulse, the resistance of the resistive element 410 may be substantially different after the programming pulse, e.g. interpreted as a low state prior to the programming pulse and a high state after the pulse. In some cases it may be desirable to configure an array of the resistive element 410 as an electrically erasable programmable read-only memory (EEPROM). In such cases it may be convenient or necessary to provide such a programming pulse from an external source.

In a second nonlimiting example, a low voltage pulse, e.g. about 2.5V may be used to program the resistive element 410. With a lower voltage programming pulse, it is expected that the time the programming pulse is active would be scaled up to deliver sufficient energy to the resistive element 410. The rise and fall times may still be short, e.g. ≲1 ns. As described previously, a relatively short fall time is expected to result in a higher resistance of the resistive element 410.

In a third nonlimiting example the resistive element 410 may be programmed from a relatively high resistance to a relatively lower resistance. A programming pulse may be used that has a longer fall time than the previously described programming pulse. As mentioned previously, a longer fall time is expected to provide a longer time period of sufficient atomic mobility to promote recrystallization of the semiconductor material within the resistive element 410. In a first more specific example a pulse may have a peak voltage of about 400 V with a duration of about 0.5 ns. The pulse may ramp down to a lower value, such as about 0 V, over a time period between about 2 ns and about 100 μs. In a second more specific example, the programming pulse may have a peak voltage of about 2.5 V, with a fall time to about 0 V in a range of about 100 ns to about 10 ms.

Factors that may be relevant in selecting a fall time include the distance between the resistive element 410 and an underlying substrate, the thermal conductivity of the substrate and materials surrounding the resistive element 410, and the heat capacity of the surrounding materials. For example, a shorter pulse length and fall time may be appropriate when the local environment of the resistive element 410 is dominated by dielectric materials, which are typically more thermally insulating, than semiconductors and metals. On the other hand, when the local environment of the resistive element 410 is dominated by more thermally conductive materials such as metal interconnect lines, a longer pulse and longer fall time may be needed to heat the resistive element 410 in a manner that results in the desired distribution of amorphous and crystalline semiconductor. Based on these factors, it is believed that a programming pulse having a duration between about 10 ns and about 10 μs with a fall time of between about 1 μs and about 1 ms may be preferable. A duration of the programming pulse between about 100 ns and about 1 μs, with a fall time of between about 10 μs and about 100 μs may be more preferable. The latter conditions may serve as a starting point from which one skilled in the pertinent art may determine more refined programming conditions reflecting the local environment of the resistive element 410.

FIG. 5 presents a top and a sectional view of an embodiment generally designated 500 of a lateral resistive storage cell based on the principles already described. A substrate 510 has an insulating layer 520, e.g. an oxide, located thereover. A semiconductor resistive element 530 overlies the insulating layer 520. Conductive paths 540, 550 may provide a programming current or a read current to the resistive element 530 by way of vias 560. In an illustrative embodiment, the resistive element 530 is formed in a polysilicon layer, the conductive paths 540, 550 are formed in a lowest metal layer, and the vias 560 are tungsten plugs. Those of skill in the pertinent art will appreciate that numerous variations are possible without departing from the scope of the disclosure.

The resistive element 530 may initially be a portion of a morphologically uniform semiconducting layer. For instance, the resistive element 530 may be a portion of a silicon-on-insulator (SOI) layer, in which case semiconductor atoms within the resistive element 530 may be initially located in uniform positions characteristic of a bulk crystalline lattice. Alternatively, in some embodiments the resistive element 530 is a portion of a polycrystalline layer. The polycrystalline layer is typically large-grained after forming the resistive element 530 using standard semiconductor device fabrication steps.

In the illustrated embodiment the resistive element 530 is configured to operate with a lateral programming current or read current. Herein and in the claims “lateral” means about parallel to the substrate 510, e.g. within about ±20° of parallel to an x-y plane as indicated by the xyz coordinate reference. The current density is greater in a narrow region 570 of the resistive element 530, resulting in greater heating within the region 570 during a programming operation than in remaining portions of the resistive element 530.

The selective heating of the region 570 may be further enhanced by selectively doping portions of the resistive element 530. For example, the region 570 may be undoped or lightly doped as compared to the other portions of resistive element 530. When doped in this manner a greater portion of the energy from a programming pulse may be deposited in the region 570 than in other portions of the resistive element 530, resulting in more localized heating. A sufficient number of vias 560 may be provided to ensure that excessive heating of the vias 560 does not occur. Heating the region 570 using a programming current heats the semiconductor material sufficiently to cause a change of morphology from a first type, e.g. polysilicon, to a different second type, e.g. amorphous.

In some embodiments the resistive element 530 is heated by an optical source, e.g. a laser. In such an embodiment, it may be preferred to provide a clear path, e.g. having no metal features, over the resistive element 530. Co-pending application Ser. No. ______ and the '976 application describe various embodiments of methods of optically heating a portion of a semiconductor to effect a change of morphology. As described therein, a laser with sufficient energy output is operated with a duty cycle and focused in a manner that results in heating of the resistive element 530 such that the morphology thereof is changed, but no significant damage to the substrate or any layers located thereover occurs.

Optical programming of the resistive element 530, or an array of such elements, may be viewed as being similar to conventional laser repair of a memory array, in which a conductive link is heated, or “blown”, by a laser. However, such a process typically damages a dielectric layer over the link, resulting in some reliability risk, and sometimes additional processing to minimize such risk. In contrast to such conventional practice, embodiments of the disclosure do not result in such damage, so additional processing is typically not needed after programming an array of resistive elements 530, and any reliability risk is expected to be negligible.

FIG. 6 illustrates an embodiment of a vertical resistive storage cell 600. A substrate 610 has an insulating layer 620, e.g. an oxide layer formed thereon. A semiconducting resistive element 630 conductively couples a lower conductive path 640 to an upper conductive path 650. The lower conductive path 640 may be, e.g. polysilicon, and the upper conductive path may be, e.g. a metal trace such as copper. Those of skill in the pertinent art are familiar with various processes that may be used to form the storage cell 600, and appreciate that various layers such as barrier layers may be used as needed to implement a particular manufacturing technology.

A programming current or a read current may flow from the lower conductive path 640 to the upper conductive path 650, or vice versa. The current flows through the resistive element 630 in a vertical direction. Herein and in the claims, vertical means about perpendicular to the substrate 610, e.g. within ±20° of a surface normal to the substrate 610 or the z-axis of the illustrated coordinate axes. The current has a higher current density within the resistive element 630 due to having a lower cross-sectional area than the lower conductive path 640 and the upper conductive path 650. The resistive element 630 is thereby heated with a time and temperature profile that results in the transformation of a region 660 from a first morphology to a different morphology. For example, the resistive element 630 may initially be polysilicon, and the region 660 may be transformed to amorphous silicon by the programming current.

In some embodiments, a semiconductor portion 670 is located between the resistive element 630 and the upper conductive path 650. The semiconductor portion 670 may have a greater cross-sectional area than the resistive element 630, and thus experience less resistive heating than the resistive element 630. In this way potential chemical reactions between the upper conductive path 650 and the resistive element 630 are reduced or minimized, decreasing the potential for reliability issues. As previously described, selective doping may enhance the heating of the resistive element 630 relative to the lower conductive path 640 and the semiconductor portion 670 by forming the resistive element 630 with a lower doping level than the lower conductive path 640 and the semiconductor portion 670. Such a doping profile may be produced, e.g. by implantation and diffusion of a dopant in a semiconductor layer from which the element 630 is formed, or by doping such a layer in-situ during deposition thereof.

In some embodiments, the resistive element 530 or the resistive element 630 is implemented as a van der Pauw or other four-terminal structure. As appreciated by those skilled in the pertinent art, the resistance of a resistive path may be determined with greater accuracy using a four-terminal structure rather than a two-terminal structure. The resistance may be determined from a four-terminal structure by well-known methods such as the Kelvin method.

FIG. 10 illustrates a four-terminal structure 1000. The structure 1000 includes a resistive element 1010 and four terminals 1020, 1030, 1040, 1050. The resistive element 1010 may be programmed, e.g. by passing a programming current between the terminals 1020, 1030. The resistance of the resistive element 1010 may then be determined by passing a read current between the terminals 1020, 1030 while sensing a resulting voltage drop using the terminals 1040, 1050. Those skilled in the pertinent arts will appreciate that many variations on the four-terminal structure 1000 are possible and within the scope of the disclosure.

Turning to FIG. 7A, illustrated is an array 700 of resistive elements configured to operate as a memory array. Resistive elements 710 are illustrated in simplified form located at intersections of word lines 720 and bit lines 730a, 730b, 730c, collectively bit lines 730. The resistive element 710 is shown without limitation as “dog-bone” structures, including contact pads and a narrow portion therebetween. The array 700 may be configured such that the resistive elements 710 are programmed by a current therethrough in a lateral direction. A word line decode block 740 and a bit line decode block 750 cooperate to select a particular resistive element 710 to be programmed or read from. If that resistive element 710 is to be programmed, a programming module such as that described with respect to FIG. 4 may also be employed.

The array 700 may be programmed to store data in any desired combination of bit values. In some cases the programming may be similar to a programmable read-only memory (PROM). For example, an external programming module may set the morphology of the resistive elements 710, after which the programmed values remain set for the life of the array 700. In other cases, the programming may be similar to that used for flash-type memory arrays. In such cases, the resistive elements 710 may be initially programmed to store first data, and later altered to store second data. In such cases, it may be preferred to locate an associated programming module on a same substrate, or within a same package, as the resistive elements 710. In yet other cases the operation of the array 700 may be similar to that of a static random access memory (SRAM), e.g. dynamically alterable to store transient data in a processor. The array 700 provides an advantage over conventional SRAM, however, in that the logic state of the storage cell in the array 700 is not as susceptible to upset.

FIG. 7B illustrates a sectional view through the long axis of the resistive element 710 of FIG. 7A. Vias 760 connect the resistive element 710 to the word line 720 and the bit line 730. The resistive element 710 includes a resistive portion 770 to which morphology changes are expected to be generally confined. A portion 780, e.g., the contact pads of the dog-bone structure, is expected to be substantially unchanged from an initial morphology of the resistive element 710.

FIG. 7C illustrates a sectional view along the long axis of the word line 720 of FIG. 7A. The illustrated embodiment is an example in which more than two resistive states of resistive elements 710 are used to store data. Resistive portions 770a, 770b, 770c are respectively located between the word line 720 and the bit lines 730a, 730b, 730c. The array 700 may be configured such that the state of the resistive portions 770 is determined by providing a current through the vias 760, e.g. in a vertical direction. In some embodiments the resistive portions 770 include a portion such as described with respect to the semiconductor portion 670 to protect the vias 760 from damage during programming of the resistive portions 770.

The resistive portion 770a is illustrated having a first morphology, e.g. polycrystalline. The resistive portion 770b is illustrated having a different second morphology, e.g. amorphous. The resistive portion 770c is illustrated having a mixture of the first morphology and the second morphology. In various embodiments the geometry of the resistive portion 770a, 770c, 770c is nominally identical, such that the resistance of each resistive portion 770a, 770b, 770c varies according to the weighted average of each morphology type therein.

In an illustrative example, the resistive portion 770a is primarily polycrystalline silicon with a resistance Rₚ, and the resistive portion 770b is primarily amorphous silicon with a resistance Rₐ. The resistive portion 770c includes volume fraction fₚ of polycrystalline silicon, and a volume fraction f_{a of amorphous silicon. The resistance of the resistive portion 770}c is therefore expected to fall between the resistances of the resistive portion 770a, 770b according to the volume fractions fₚ, fₐ. If fₚ=fₐ=0.5, then the resistance of the resistive portion 770c is expected to be about midway between the resistance of the resistive portion 770a and the resistance of the resistive portion 770b. Thus, in this example the resistive element may be one of three discrete values, Rₐ, Rₚ or (Rₐ+Rₚ)/2.

In another illustrative example, fₚ≈⅓, and fₐ≈⅔. In this case the resistance of the resistive portion 770c is expected to be about equal to the resistance of the resistive portion 770a (e.g. polycrystalline) plus the difference between the resistance of the resistive portion 770a and the resistive portion 770b (e.g. amorphous). On the other hand, if fₚ≈⅔, and fₐ≈⅓, then the resistance of the resistive portion 770c is expected to be about equal to the resistance of the resistive portion 770a plus ⅔ the difference between the resistance of the resistive portion 770a and the resistive portion 770b. Thus, in this example the resistive portion 770c may have one of four discrete values: Rₐ, Rₚ, (2Rₐ+Rₚ)/3 or (Rₐ+2Rₚ)/3.

The principles illustrated by these two examples may be extended to any number of discrete resistance values within the capability of a read module, e.g. the read module 430, to resolve the values. The multiple discrete values, greater than two, provide the ability to reduce the number of resistive elements 710 (FIG. 7) needed to store a number of bits of information. For example, if four discrete resistance values are used, then 256 states normally encodable in an 8-bit binary byte may be represented by only 4 digits. If 16 discrete resistance values are provided, only two digits are needed to convey the same data as the 8-bit byte using binary encoding. Such compression of data representation provides a means to significantly reduce the area needed to provide data storage on an electronic device, e.g. the device 400.

In various embodiments the electronic device 400 is manufactured using conventional processing technology, such as a multilevel CMOS process flow. Such processes are known to those skilled in the semiconductor manufacturing arts. In some embodiments, multiple levels of memory may be formed over the same substrate, with some memory arrays overlapping. The resistive elements making up this array are not limited to one semiconductor layer, but can be defined in one or more successive semiconductor layers, and/or in one or more interconnect layers by taking advantage of semiconductor fabrication process capabilities. In this way the overall memory size achievable for a given die area may be significantly greater than for a conventional memory architecture.

Turning now to FIG. 8A, illustrated is an embodiment of a method, generally designated 800, of forming an electronic device such as the device 400. The steps of the method 800 are described without limitation by reference to the embodiments of FIGS. 4, 5, 6, 7A, 7B, 8A and 8B. The steps of the method 800 may be performed in an order different than the illustrated order.

In a step 810, a substrate, e.g. the substrate 510 or the substrate 610, is provided that has a semiconductor region located thereover, e.g., the region 570 or the region 660. The semiconductor region has a morphology of a first type. Herein and in the claims, “provided” or “providing” means that a device, substrate, structural element, etc., may be manufactured by the individual or business entity performing the disclosed methods, or obtained thereby from a source other than the individual or entity, including another individual or business entity.

In a step 820 at least a portion of the semiconductor region, e.g. the region 570 or the region 660, is converted to a morphology of a second type that is different from the first type. The converting may be by, e.g. an electrical stimulus or illumination with electromagnetic radiation.

In a step 830 the semiconductor region is resistively coupled to a read module, e.g. the read module 430. The read module is configured to convert a resistance of said region to a logic level. Optionally, the read module 430 is formed over the same substrate as the resistive region.

FIG. 8B illustrates optional steps of the method 800. These optional steps may also be performed, if at all, in an order different from the illustrated order. In a step 840 a programming module, e.g. the programming module 420, is configured to convert the resistive region using a lateral current. In this step a read module such as the read module 430 may also be configured to determine the resistive state of the region using a vertical current through the resistive region.

In a step 850 the resistive region is configured as a four-terminal structure, as described previously. A first terminal pair of the four-terminal structure is configured to provide a programming current through the resistive element. The first terminal pair or a second terminal pair of the four-terminal structure is configured to provide a read current through the resistive element. To determine the voltage that results from the read current, a voltage sensor may be connected across the terminal pair not carrying the read current. In some cases a four-terminal method such as the Kelvin method may be used.

In a step 860 a programming module, e.g., the programming module 420, is configured to produce a current density through the resistive element of at least about 10⁶ A/cm². In a step 870 a programming module is configured to produce within the resistive element a programming signal including a pulse with a voltage and a rise and/or fall time selected to convert a portion of the resistive element from a first morphology to a different second morphology as described with respect to the resistive element 410. In a step 880 a read module is configured to convert a resistance of the resistive element to one of at least three logic levels.

Those skilled in the art to which this application relates will appreciate that other and further additions, deletions, substitutions and modifications may be made to the described embodiments.

What is claimed is:

1. An electronic device, comprising:
a substrate;
a resistive element including a semiconductor region formed over said substrate;
a read module configured to determine a resistance of said resistive element; and
a programming module configured to cause a current to flow through said semiconductor region, said current being sufficient to induce a change of morphology of at least a portion of said semiconductor region.

2. The electronic device recited in claim 1, wherein said resistive element includes an amorphous region and a crystalline region that share an intimate interface.

3. The electronic device recited in claim 2, wherein said crystalline region includes fine-grained polycrystalline semiconductor material.

4. The electronic device recited in claim 1, wherein said read module is configured to convert said resistance to one of at least three different logic levels.

5. The electronic device recited in claim 1, further comprising:
a plurality of resistive elements configured to operate as a memory; and
bit lines and word lines configured to address individual ones of said resistive elements.

6. The electronic device recited in claim 6, wherein said resistive elements are located between said bit lines and said word lines.

7. The electronic device recited in claim 1, wherein said read module is located on said substrate.

8. An electronic device, comprising:
a semiconductor substrate;
a resistive element located over said substrate and configured to receive a read current, said element including:
an amorphous region of a semiconductor material; and
a crystalline region of said semiconductor material that forms an intimate interface with said amorphous region.

9. The electronic device recited in claim 8, further comprising a read module conductively coupled to said amorphous region and said crystalline region, said read module being configured to determine a resistance of said resistive element.

10. The electronic device recited in claim 8, wherein said crystalline region is polycrystalline.

11. The electronic device recited in claim 8, further comprising a programming module configured to produce a current density in said resistive element of at least about 10⁶ A/cm².

12. The electronic device recited in claim 8, further comprising a read module configured to convert a resistance of said resistive element to one of at least two logic levels.

13. The electronic device recited in claim 12, wherein said at least two logic levels is at least three logic levels.

14. The electronic device as recited in claim 8, wherein said resistive element is configured to laterally conduct a programming current therethrough, and to vertically conduct a read current therethrough.

15. The electronic device as recited in claim 8, wherein said resistive element is configured as a four-terminal device.

16. The electronic device as recited in claim 8, wherein said first and second semiconductor regions are portions of a resistive element of a device selected from the group consisting of:
a logic array;
a static random access memory; and
a programmable read-only memory.

17. A method of forming an electronic device, comprising:
providing a substrate having a semiconductor region located thereover configured to receive a current, said semiconductor region having a morphology of a first type;
converting at least a portion of said semiconductor region to a morphology of a different second type; and
resistively coupling said semiconductor region to a read module, said read module being configured to convert a resistance of said region to a logic level.

18. The method as recited in claim 17, further comprising configuring a programming module to perform said converting using a current through said resistive element about parallel to said substrate, and configuring said read module to provide a current through said resistive element about perpendicular to said substrate.

19. The method as recited in claim 17, further comprising configuring said resistive element as a four-terminal structure, configuring a first terminal pair of said four-terminal structure to provide a programming current through said resistive element, and configuring said first terminal pair or a second terminal pair of said four-terminal structure to provide a read current through said resistive element.

20. The method as recited in claim 17, further comprising configuring a programming module to produce a current density in said resistive element of at least about 10⁶ A/cm².

21. The method as recited in claim 17, further comprising configuring a programming module to produce within said resistive element a programming signal including a voltage pulse having a fall time of less than about 10 ns.

22. The method as recited in claim 17, further comprising configuring a read module to convert a resistance of said resistive element to one of at least three logic levels.

23. The method as recited in claim 17, wherein said morphology of a second type is amorphous.

24. The method as recited in claim 17, wherein said first and second regions are portions of a resistive element of a device selected from the group consisting of:
a logic array;
a static random access memory; and
a programmable read-only memory.
